(19) United States
(12) Patent Application Publication
(10) Pub. No.: US 2018/0302090 A1
(43) Pub. Date: Oct. 18, 2018

(54) CAPACITIVE KEYBOARD

(71) Applicant: DAY-RONG HUNG, Taichung City (TW)

(72) Inventor: DAY-RONG HUNG, Taichung City (TW)

(73) Assignee: Sunrex Technology Corp., Taichung City (TW)

(21) Appl. No.: 15/488,493

(22) Filed: Apr. 16, 2017

(51) Int. Cl. H03K 17/96; G06F 3/02

(52) U.S. Cl. CPC H03K 17/9622; G06F 3/0202

(57) ABSTRACT

A capacitive keyboard includes key caps, bridge structures, hollow, resilient domes, truncated conic springs, a frame board, a base board, and a circuit board. An upper part of the bridge structure is pivotably secured to the key cap and a lower part thereof is pivotably secured to the frame board, thereby forming a bridge type press button structure. The resilient dome is disposed on a frame board. The resilient dome is through the bridge structure to secure to the key cap. The truncated conic spring is partially disposed in the resilient dome and biases against the resilient dome. The circuit board includes capacitive sensors each with the truncated conic spring disposed thereon. Force exerted on the key cap changes capacitance of the capacitive sensor which in turn sends a key press signal which has a strength proportional to the force exerted on the key cap.

### BACKGROUND OF THE INVENTION

### 1. Field of the Invention

The invention relates to keyboards and more particularly to a thin, capacitive keyboard having a truncated conic spring under each key, the spring being capable of triggering a capacitive sensor to send a key press signal in response to a compression degree of the spring.

### 2. Description of Related Art

Keyboards are main input devices of computer or the like. For example, Taiwan Utility Model Number M509969 discloses a keyboard having a plurality keys each being capable of sending a key press signal in response to force exerted thereon.

However, the prior art suffers from a number of drawbacks due to the provision of stem under the key. In detail, the keys are bulky rather than being compact, thin. The key cap may deflect to either right or left (i.e., oblique) after a period of time of use. Thus, a correct key press signal cannot be generated in response to a key press and a subsequent downward movement of the stem.

Thus, the need for improvement still exists.

### SUMMARY OF THE INVENTION

It is therefore one object of the invention to provide a capacitive keyboard comprising a plurality of key caps, a plurality of bridge structures, a plurality of hollow, resilient domes, a plurality of truncated conic springs, a frame board, a base board, and a circuit board, wherein each key cap is a square or rectangle, and is adapted to be depressed; each bridge structure includes a hollow, rectangular first member and a hollow, rectangular second member pivotably secured to the first member; and an upper part of the bridge structure is pivotably secured to the key cap and a lower part thereof is pivotably secured to the frame board, thereby forming a bridge type press button structure; the resilient dome is disposed on a frame board including a plurality of openings; and the resilient dome is disposed through the bridge structure to secure to a bottom of the key cap; the truncated conic spring is partially disposed in the resilient dome and has a top biased against a bottom of the resilient dome; the frame board includes a plurality of units each having a central hole with the truncated conic spring disposed through; the base board includes a plurality of positioning holes; the circuit board includes a plurality of a capacitive sensors each the truncated conic spring disposed thereon; force exerted on the key cap is transmitted to compress the truncated conic spring via the resilient dome so that force exerted on the capacitive sensor by the truncated conic spring is changed, thereby changing capacitance of the capacitive sensor which sends a key press signal in response to a compression degree of the truncated conic spring; and strength of the key press signal is proportional to the capacitance change which in turn is proportional to the force exerted on the key cap.

The above and other objects, features and advantages of the invention will become apparent from the following detailed description taken with the accompanying drawings.

### BRIEF DESCRIPTION OF THE DRAWINGS

FIG. 1 is a perspective view of a key and associated components according to a first preferred embodiment of the invention;

FIG. 2 is an exploded view of FIG. 1;

FIG. 3 is an exploded view of the bridge structure;

FIG. 4A is a longitudinal sectional view of FIG. 1;

FIG. 4B is a view similar to FIG. 4A showing a pressing of the key cap;

FIG. 5 is a longitudinal sectional view of a key and associated components according to a second preferred embodiment of the invention; and

FIG. 6 is a perspective view of a capacitive keyboard incorporating the keys and the associated components according to the invention.

### DETAILED DESCRIPTION OF THE INVENTION

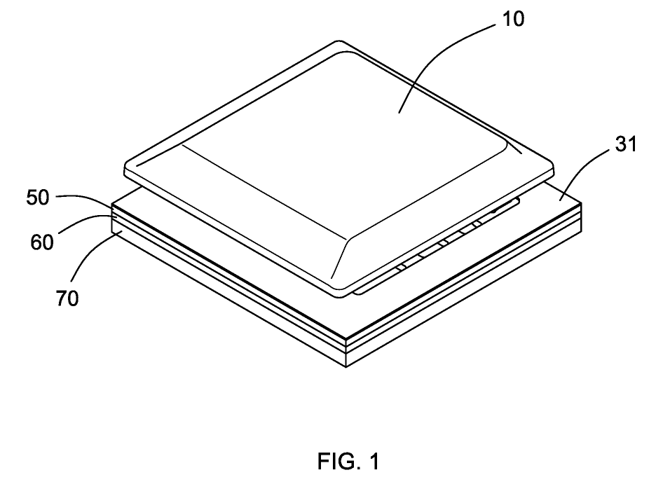

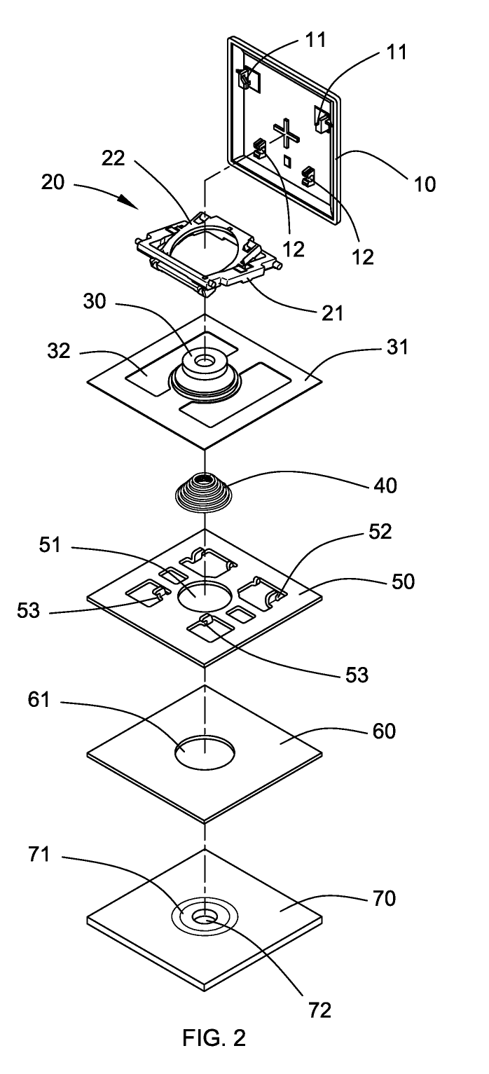

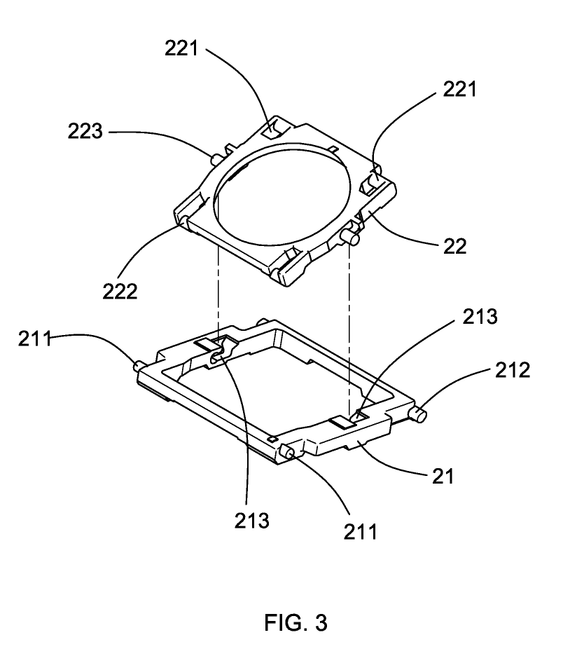

Referring to FIGS. 1 to 4 and 6, a capacitive keyboard 1 in accordance with a first preferred embodiment of the invention comprises the following components as discussed in detail below.

The keyboard 1 comprises, from top to bottom, a plurality of key caps 10, a plurality of bridge structures 20, a plurality of hollow, resilient domes 30, a plurality of truncated conic springs 40, a frame board 50, a base board 60, and a circuit board 70. Each component is discussed in detail below.

Each key cap 10 is a square or rectangle, and is adapted to be depressed. Each key cap 10 on its underside has two spaced troughs 11 proximate one edge and two spaced guide grooves 12 proximate the other edge

The bridge structure 20 includes a hollow, rectangular first member 21 and a hollow, rectangular second member 22. The first member 21 has two first pivots 211 at two corners respectively and pivotably fastened in the troughs 11 respectively, two second pivots 212 at two other corners respectively, and two wells 213 at two sides respectively. The second member 22 has two first pivot shafts 221 at two corners respectively and pivotably mounted in the guide grooves 12 respectively, two second pivot shafts 222 at two corners respectively, and two laterally extending pins 223 at two sides respectively and pivotably mounted in the wells 213 respectively.

The resilient dome 30 is provided on a frame board 31 having a plurality of openings 32. The resilient dome 30 is disposed through the bridge structure 20 to secure to a bottom of the key cap 10. The truncated conic spring 40 is partially disposed in the resilient dome 30 and has a top biased against the bottom of the resilient dome 30.

The frame board 50 includes a plurality of units each having a central hole 51 with the truncated conic spring 40 disposed through, two spaced snapping grooves 52 with the second pivots 212 pivotably fastened therein respectively, and two spaced inverted L-shaped guide grooves 53 with the second pivot shafts 222 pivotably fastened therein respectively. Thus, the bridge structure 20 is adapted to pivot between the key cap 10 and the frame board 50, thereby forming a bridge type press button structure.

The base board 60 includes a plurality of positioning holes 61 each aligned with the central hole 51 and with the bottom of the truncated conic spring 40 disposed therein. The circuit board 70 includes a plurality of holes 72 each aligned with the positioning hole 61, and a plurality of a capacitive sensors 71 each formed around the hole 72 and with the bottom of the truncated conic spring 40 disposed thereon.

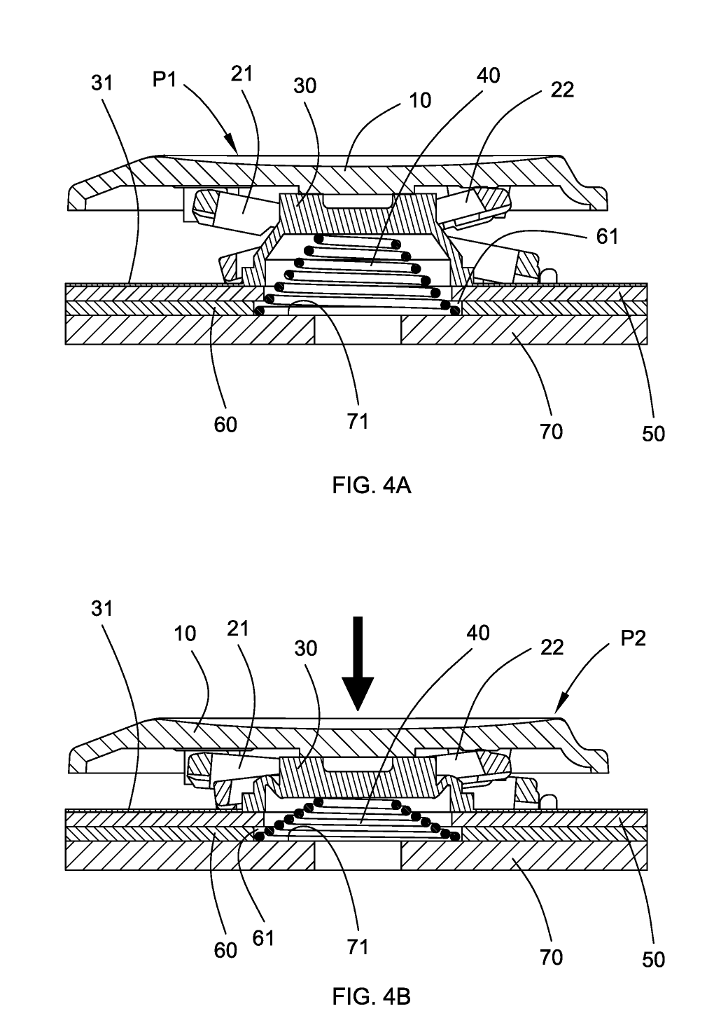

In an inoperative state, the key cap 10 is disposed in a first position indicated by P1 (see FIG. 4A). In response to pressing the key cap 10, the key cap 10 is disposed in a second position indicated by P2 (see FIG. 4B). In the second position P2, the truncated conic spring 40 is compressed because the force exerted by the finger on the key cap 10 is transmitted to the truncated conic spring 40 via the resilient dome 30. And in turn, force exerted on the capacitive sensor 71 by the truncated conic spring 40 is changed (i.e., increased), thereby changing capacitance of the capacitive sensor 71. As a result, the capacitive sensor 71 sends a key press signal in response to a compression degree of the truncated conic spring 40. It is noted that strength of the key press signal is proportional to the capacitance change which in turn is proportional to the force exerted on the key cap 10.

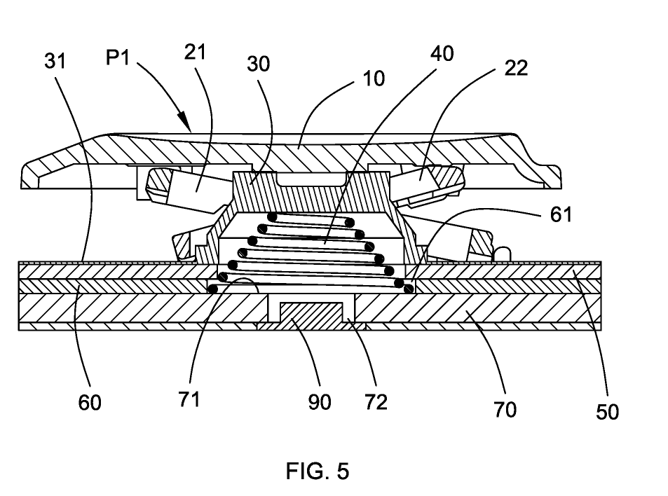

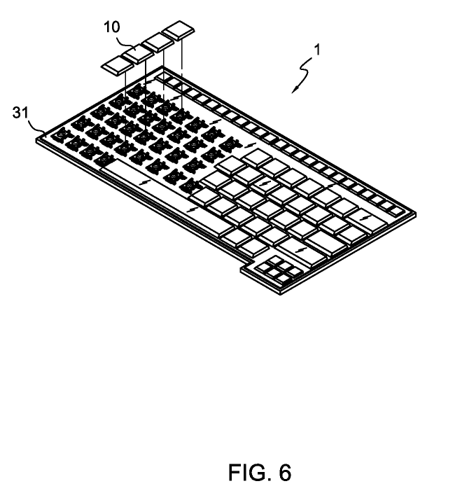

Referring to FIG. 5 in conjunction with FIG. 6, a capacitive keyboard 1 in accordance with a second preferred embodiment of the invention is shown. The characteristics of the second preferred embodiment are substantially the same as that of the first preferred embodiment except the following: A light emitting member (e.g., light-emitting diode (LED)) 90 is provided in each hole 72 so that the key cap 10 can be illuminated by the light emitting member 90 when an individual uses the keyboard 1 in a dark environment.

While the invention has been described in terms of preferred embodiments, those skilled in the art will recognize that the invention can be practiced with modifications within the spirit and scope of the appended claims.

1.-6. (canceled)

7. A capacitive keyboard comprising a plurality of key caps, a plurality of bridge structures, a plurality of hollow resilient domes, a plurality of truncated conic springs, a first frame board, a base board, and a circuit board, wherein
each key cap is a square or rectangle, and is adapted to be depressed;
each bridge structure includes a hollow rectangular first member and a hollow rectangular second member pivotably secured to the first member; and an upper part of the bridge structure is pivotably secured to the key cap and a lower part thereof is pivotably secured to the first frame board, thereby forming a bridge type press button structure;
each resilient dome is disposed on a second frame board including a plurality of openings; and each resilient dome is disposed through one of the bridge structures to secure to a bottom of one of the key caps;
each truncated conic spring is partially disposed in one of the resilient domes and has a top biased against a bottom of the resilient dome;
the first frame board includes a plurality of units each having a central hole with the truncated conic spring disposed through, two spaced snapping grooves with the second pivots pivotably fastened therein respectively, and two spaced inverted L-shaped guide grooves with the second pivot shafts pivotably fastened therein respectively;
the base board Includes a plurality of positioning holes;
the circuit board includes a plurality of a capacitive sensors each with the truncated conic spring disposed thereon;
each key cap on its underside includes two spaced troughs proximate one edge and two spaced guide grooves proximate the other edge; the first member has two first pivots at two corners respectively and pivotably fastened in the troughs respectively, two second pivots at two other corners respectively, and two wells at two sides respectively; and the second member has two first pivot shafts at two corners respectively and pivotably mounted in the guide grooves respectively, two second pivot shafts at two corners respectively, and two laterally extending pins at two sides respectively and pivotably mounted in the wells respectively.
each positioning hole of the base board is aligned with both the central hole and the capacitive sensor;
force exerted on the key cap is transmitted to compress the truncated conic spring via the resilient dome, a compression degree of the compressed truncated conic spring is proportional to the force, and a changing capacitance of the capacitive sensor is proportional to the compression degree of the truncated conic spring so that the force exerted on the truncated conic spring is detected, thereby changing capacitance of the capacitive sensor in proportion to the compression degree of the truncated conic spring and the capacitive sensor sends a key press signal in response to the compression degree of the truncated conic spring; and
strength of the key press signal is proportional to the capacitance change which in turn is proportional to the force exerted on the key cap.
